(19) United States
(12) Patent Application Publication
(10) Pub. No.: US 2023/0320153 A1
(43) Pub. Date: Oct. 5, 2023

(54) DISPLAY APPARATUS

(71) Applicant: LG Display Co., Ltd., Seoul (KR)

(72) Inventor: TaeRyong Kim, Paju-si (KR)

(73) Assignee: LG Display Co., Ltd., Seoul (KR)

(21) Appl. No.: 18/127,967

(22) Filed: Mar. 29, 2023

(30) Foreign Application Priority Data
Mar. 31, 2022 (KR) 10-2022-0040667

(51) Int. Cl. H10K 59/131; H10K 59/124; G06F 3/041; G06F 3/044

(52) U.S. Cl. CPC H10K 59/131; H10K 59/124; G06F 3/0412; G06F 3/0445; H10K 59/40

(57) ABSTRACT

A display apparatus may include a substrate including a display portion, and a non-display portion at a periphery of the display portion and including a pad area. The display apparatus may further include a plurality of signal lines at the display portion and the non-display portion, a plurality of pads respectively connected with the plurality of signal lines in the pad area, and an insulation layer on the substrate between the plurality of pads. A first distance between the substrate and a center portion of the insulation layer may be smaller than a second distance between the substrate and a periphery portion of the insulation layer.

### CROSS-REFERENCE TO RELATED APPLICATIONS

This application claims the benefit of and priority to Korean Patent Application No. 10-2022-0040667 filed on Mar. 31, 2022, the entirety of which is hereby incorporated by reference.

### BACKGROUND

### Technical Field

The present disclosure relates to a display apparatus.

### Discussion of the Related Art

Display apparatuses, applied to monitors of computers, televisions, mobile electronic devices, home appliances, or vehicles, include organic light emitting display apparatuses self-emitting light and liquid crystal display (LCD) apparatuses employing a separate light source.

Recently, because display elements and connection lines are formed on a substrate having flexibility like plastic which is a flexible material, flexible display apparatuses are manufactured to display an image despite being bent like paper and thus are attracting much attention as next-generation display apparatuses.

### SUMMARY

Accordingly, the present disclosure is directed to a display apparatus that substantially obviates one or more of the problems due to limitations and disadvantages of the related art.

An aspect of the present disclosure is directed to providing a display apparatus which may prevent or minimize the partial detachment and/or stripping of a layer at an interface between an insulation layer and a pad.

Additional features and aspects of the disclosure will be set forth in the description that follows, and in part will become apparent from the description or may be learned by practice of the inventive concepts provided herein. Other features and aspects of the inventive concepts may be realized and attained by the structure particularly pointed out in, or derivable from, the written description, claims hereof, and the appended drawings.

To achieve these and other aspects of the inventive concepts, as embodied and broadly described herein, a display apparatus may include: a substrate including a display portion and a non-display portion at a periphery of the display portion and including a pad area; a plurality of signal lines at the display portion and the non-display portion; a plurality of pads respectively connected with the plurality of signal lines in the pad area; and an insulation layer on the substrate between the plurality of pads, wherein a first distance between the substrate and a center portion of the insulation layer may be smaller than a second distance between the substrate and a periphery portion of the insulation layer.

In another aspect, a display apparatus may include: a substrate including a display region and a non-display region surrounding the display region; a plurality of pads disposed in the non-display region and respectively connected with a plurality of signal lines for supplying signals to a plurality of pixels disposed in the display region; and an insulation layer disposed on the substrate and contacting with at least a portion of a side surface of each of the plurality of pads, wherein a thickness of the insulation layer may decrease progressively toward a center portion of the insulation layer from an end of the insulation layer.

According to the present disclosure, because an insulation layer having a non-flat (or nonplanar) structure is provided between a plurality of pads, the partial detachment and/or stripping of a layer at an interface between the insulation layer and the pads may be minimized.

In addition to the above-mentioned advantages of the present disclosure, other features and advantages of the present disclosure will be described below or may be clearly understood by those skilled in the art from such description or explanation.

Other systems, methods, features, and advantages will be, or will become, apparent to one with skill in the art upon examination of the following figures and detailed description. It is intended that all such additional systems, methods, features, and advantages be included within this description and be within the scope of the present disclosure. Nothing in this section should be taken as a limitation on the claims. Further aspects and advantages are discussed below in conjunction with embodiments of the disclosure.

It is to be understood that both the foregoing general description and the following detailed description of the present disclosure are by way of example and are intended to provide further explanation of the disclosures as claimed.

### BRIEF DESCRIPTION OF THE DRAWINGS

The accompanying drawings, which are included to provide a further understanding of the disclosure and are incorporated in and constitute a part of this application, illustrate aspects and embodiments of the disclosure and together with the description serve to explain principles of the disclosure.

FIG. 1 is a plan view of a display apparatus according to an embodiment of the present disclosure.

FIG. 2 is an example of a cross-sectional view taken along line II-IF of FIG. 1.

FIG. 3 is an example of an enlarged view of a region III of FIG. 1.

FIG. 4 is an example of a cross-sectional view taken along line A-A′ of FIG. 3.

FIG. 5 is a diagram for describing another example of a cross-sectional view taken along line A-A′ of FIG. 3.

FIG. 6 is another example cross-sectional view taken along line A-A′ of FIG. 3.

FIG. 7 is an example cross-sectional view taken along line B-B′ of FIG. 3.

FIG. 8 is another example enlarged view of a region III of FIG. 1.

FIG. 9 is an example cross-sectional view taken along line C-C′ of FIG. 8 and of FIG. 10.

FIG. 10 is another example enlarged view of a region III of FIG. 1.

FIG. 11 is an example cross-sectional view taken along line D-D′ of FIG. 10.

FIG. 12 is another example cross-sectional view taken along line A-A′ of FIG. 3.

Throughout the drawings and the detailed description, unless otherwise described, the same drawing reference numerals should be understood to refer to the same elements, features, or structures. The relative size and depiction of these elements may be exaggerated for clarity, illustration, or convenience.

### DETAILED DESCRIPTION

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents.

The terms used in example embodiments of the present disclosure may be selected from among general terms which are currently and widely used, based on functions of the present disclosure, but may be altered according to the intent or precedent of persons skilled in the art or the advent of new technology. Also, depending on the case, some terms may be arbitrarily determined by the applicant, and in this case, meanings thereof may be described in detail in a corresponding description. Therefore, the terms used in example embodiments of the present disclosure should be defined on the basis of the entire content of this specification, not solely on a simple name of the term.

In embodiments of the present disclosure below, where one is described to comprise (or include or have) some elements, it should be understood that it may comprise (or include or have) only those elements, or it may comprise (or include or have) one or more additional elements as well as those identified elements if there is no specific limitation.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The shapes, sizes, areas, ratios, angles, numbers, and the like illustrated in the drawings for describing various example embodiments of the present disclosure are merely examples. Thus, the present disclosure is not limited to such illustrated details in the drawings. In the following description, where the detailed description of the relevant known function or configuration may unnecessarily obscure aspects of the present disclosure, the detailed description of such known function or configuration may be omitted.

Where the terms “comprise,” “have,” “include,” “contain,” “constitute,” “make up of,” “formed of,” and the like are used in the present specification, one or more other elements may be added unless a more limiting term, such as “only,” is used. An element described in the singular form is intended to include a plurality of elements, and vice versa, unless the context clearly indicates otherwise. In construing an element, the element is to be construed as including an error or tolerance range even where no explicit description of such an error or tolerance range is provided.

In describing a positional relationship, for example, where the positional relationship between two parts is described using “on,” “over,” “under,” “above,” “below,” “beneath,” “near,” “close to,” “adjacent to,” “beside,” “next to,” or the like, one or more other parts may be located between the two parts unless a more limiting term, such as “immediate(ly),” “direct(ly),” or “close(ly)” is used. For example, where a structure is described as being positioned “on,” “over,” “under,” “above,” “below,” “beneath,” “near,” “close to,” “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom,” “downward,” “upward,” “upper,” “lower,” and the like refer to an arbitrary frame of reference. A device or a layer being referred to as being “on” another device or layer may include all cases where the device or layer is disposed or interposed just on the other device or the other layer or at a middle portion thereof, unless otherwise specified.

Although the term “first,” “second,” or the like may be used herein to describe various elements, these elements should not be limited by these terms as they are not used to define, for example, any particular order, precedence, or number of elements. These terms are only used to distinguish one element from another. For example, the first element described below could be termed a second element, and a second element could similarly be termed a first element, without departing from the scope of the present disclosure. Furthermore, such expressions as “first,” “second,” “third,” or the like may be terms used to distinguish elements from each other in each example embodiment, but the functions or structures of the elements are not limited by ordinal numbers or component names in front of the elements. Therefore, the same terms may denote different elements, based on embodiments.

In addition, for convenience of description, an area, dimension, a length, a height, a size, or a thickness of each of the elements in the accompanying drawings is illustrated to be enlarged or reduced, and a scale, dimension, a length, a height, a size, or a thickness of each of the elements illustrated in the drawings of the present disclosure may differ from an actual scale, dimension, a length, a height, a size, or a thickness. Thus, embodiments of the present disclosure are not limited to a scale, a length, a height, a size, or a thickness illustrated in the drawings.

Features of various embodiments of the present disclosure may be partially or entirely coupled to or combined with each other. They may be linked and operated technically in various ways as those skilled in the art can sufficiently understand. The embodiments may be carried out independently of or in association with each other in various combinations.

Moreover, the terms described below may be terms which are defined in consideration of functions in an example embodiment of the present disclosure and may be altered based on the intent of a user or operator, or on conventional practice. Therefore, definitions thereof should be based on the entire details of the present disclosure.

A transistor configuring a pixel circuit of the present disclosure may include one or more of an oxide thin film transistor (TFT), amorphous silicon (a-Si) TFT (a-Si TFT), and a low temperature polysilicon (LTPS) TFT.

In the following embodiments, an organic light emitting display apparatus will be described mainly. However, embodiments of the present disclosure are not limited to an organic light emitting display apparatus and may be applied to other types of display apparatuses, including a micro light emitting diode display apparatus or an inorganic light emitting display apparatus including an inorganic light emitting material. For example, embodiments of the present disclosure may be applied to a quantum dot display apparatus.

Hereinafter, embodiments of the present disclosure will be described in detail with reference to the accompanying drawings.

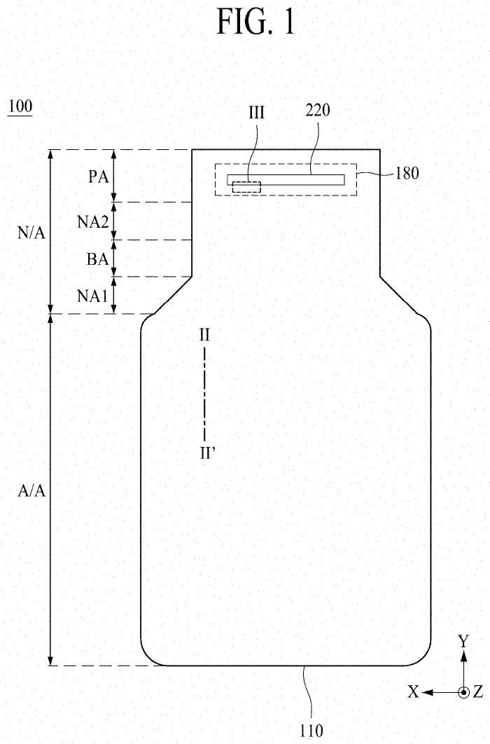

FIG. 1 is a plan view of a display apparatus according to an example embodiment of the present disclosure.

As illustrated in FIG. 1, the display apparatus 100 according to an example embodiment of the present disclosure may include a substrate 110 which includes a display area (a display portion) A/A and a non-display area (a non-display portion) N/A.

The substrate 110 may be a substrate having ductility and may be a substrate for supporting several elements of the display apparatus 100. The substrate 110 may include a material having flexibility and, for example, may include a plastic material, such as polyimide (PI), but embodiments of the present disclosure are not limited thereto.

The display area A/A may be an area which includes a plurality of pixels and is configured to display an image. Each of the plurality of pixels may include a plurality of sub-pixels. A display portion configured to display an image and a circuit unit configured to drive the display portion may be provided at the display area A/A. For example, where the display apparatus 100 is a light emitting display apparatus, the display portion may include a light emitting device. For example, the display portion (or a pixel or a light emitting device) may include a first electrode, an emission structure on the first electrode, and a second electrode on the emission structure. For example, the emission structure may include a light emitting layer or an organic light emitting layer. For example, the emission structure may be configured with a hole transport layer, a hole injection layer, a hole blocking layer, an organic light emitting layer, an electron injection layer, an electron blocking layer, and an electron transport layer, but embodiments of the present disclosure are not limited thereto. For example, where the display apparatus 100 is a liquid crystal display apparatus, the display portion may be configured to include a liquid crystal layer. Hereinafter, for convenience of description, an example where the display apparatus 100 is an organic light emitting display apparatus will be described, but embodiments of the present disclosure are not limited thereto.

The circuit unit (or a pixel circuit) may include various thin film transistors (TFTs), a capacitor, and a line which are configured to drive the light emitting device. For example, the circuit unit may include various elements, such as a driving TFT, a switching TFT, a storage capacitor, a gate line, and a data line, but embodiments of the present disclosure are not limited thereto.

As shown in FIG. 1, the display area A/A may have a shape with rounded corners. Recently, as a design aspect is emphasized, there may be a demand for the display area A/A with a shape other than a rectangular shape. Therefore, the substrate 110 of the display apparatus 100 may have a rounded corner shape. For example, the substrate 110 may have a shape where two or more corners are rounded. However, a shape of the display area A/A is not limited thereto. According to other example embodiments, the display area A/A may have other shapes, such as a tetragonal shape, a non-tetragonal shape, and a non-tetragonal shape including at least one curved surface.

The non-display area N/A may be an area which does not display an image. For example, the non-display area N/A may be an area where various lines, such as a plurality of signal lines, and a circuit for driving the display portion disposed in the display area A/A are provided. In addition, various integrated circuits (ICs), such as a gate driver circuit (or a gate driver IC) for applying a signal to a gate line and a data driver IC for applying a signal to a data line, and driving circuits may be disposed in the non-display area N/A. For example, an integrated driver IC into which the gate driver IC and the data driver IC are integrated may be disposed in the non-display area N/A.

The non-display area N/A may be an area which extends from the display area A/A. However, embodiments of the present disclosure are not limited thereto, and the non-display area N/A may include an area which surrounds the display area A/A. In addition, the non-display area N/A may extend from a plurality of sides of the display area A/A. For example, the non-display area N/A may be an area which extends from one side of the display area A/A.

As illustrated in FIG. 1, the non-display area N/A may include a first non-display area NA1, a bending area BA, a second non-display area NA2, and a pad area PA.

The first non-display area NA1 may be an area which extends from the display area A/A. The bending area BA may be an area which extends from the first non-display area NA1 and may be a bent or bendable area. The second non-display area NA2 may be an area which extends from the bending area BA. The pad area PA may be an area which extends from the second non-display area NA2. For example, the bending area BA may be between the first non-display area NA1 and the second non-display area NA2. For example, the first non-display area NA1, the bending area BA, and the second non-display area NA2 may have different sizes (or planar areas), but embodiments of the present disclosure are not limited thereto.

The pad area PA may include a plurality of pads. The pad area PA may include a circuit disposition area 180. For example, the pad area PA may include a plurality of pads and a circuit disposition area 180 which overlaps at least a portion of each of the plurality of pads.

A driving circuit (or a driving IC) 220 may be disposed in or attached on the circuit disposition area 180. The driving circuit 220 may be disposed in or attached on the circuit disposition area 180 so as to be electrically connected with or to contact at least a portion of each of the plurality of pads. For example, the driving circuit 220 may be disposed in or attached on the circuit disposition area 180 in a chip on panel (COP) type and may be electrically connected with or may contact at least a portion of each of the plurality of pads. For example, the driving circuit 220 may be electrically connected with or may contact at least a portion of each of the plurality of pads via an anisotropic conductive film or the like. Accordingly, the driving circuit 220 may be electrically connected with the plurality of pads and may transfer an electrical signal to the display area A/A (or one or more pixels).

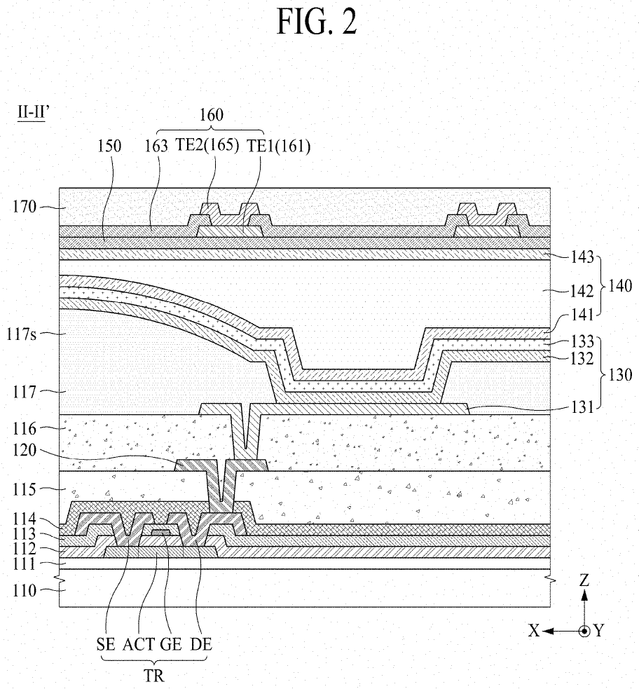

FIG. 2 is an example cross-sectional view taken along line II-IF of FIG. 1. FIG. 2 is a cross-sectional view illustrating a cross-sectional structure of one example pixel.

As shown in FIG. 2, the display apparatus 100 or the display area A/A of the display apparatus 100 according to an example embodiment of the present disclosure may include the substrate 110, a buffer layer 111, a transistor TR, a light emitting device 130, and an encapsulation portion 140.

The buffer layer 111 may be disposed on the substrate 110. The buffer layer 111 may enhance an adhesive force between the substrate 110 and layers formed on the buffer layer 111. The buffer layer 111 may block an alkali component leaked from the substrate 110. In addition, the buffer layer 111 may be omitted based on the kind and material of the substrate 110 and a structure and a conduction type of the transistor TR.

The transistor TR may be disposed on the buffer layer 111. The transistor TR may include an active layer ACT, a gate electrode GE, a source electrode SE, and a drain electrode DE. For example, based on a design of the pixel circuit or a conduction type of the transistor TR, the source electrode SE may be the drain electrode DE, and the drain electrode DE may be the source electrode SE. In the display area A/A of the substrate 110, the active layer ACT of the transistor TR may be disposed on the buffer layer 111.

The active layer ACT may include a channel region, where a channel is formed in driving of the transistor TR, and a source region and a drain region at respective sides of the channel region. The source region may be a portion of the active layer ACT connected with the source electrode SE, and the drain region may be a portion of the active layer ACT connected with the drain electrode DE.

The active layer ACT may include, for example, various metal oxides, such as indium-gallium-zinc-oxide (IGZO). An example has been described where the active layer ACT of the transistor TR includes IGZO of various metal oxides and is formed based on an IGZO layer. But embodiments of the present disclosure are not limited thereto, and the active layer ACT may include other metal oxide, such as indium-zinc-oxide (IZO), indium-gallium-tin-oxide (IGTO), or indium-gallium-oxide (IGO), or the like, rather than IGZO. The active layer ACT may be formed by patterning metal oxide after the metal oxide is deposited on the buffer layer 111 and a thermal treatment process for stabilization is performed.

A first insulation layer (or a gate insulation layer) 112 may be disposed on the active layer ACT of the transistor TR. The first insulation layer 112 may include an inorganic material and, for example, may include a single layer, including nitride silicon (SiNx) or oxide silicon (SiOx), or a multilayer thereof. Contact holes for respectively connecting the source electrode SE and the drain electrode DE of the transistor TR with the source region and the drain region of the active layer ACT of the transistor TR may be formed at the first insulation layer 112.

The gate electrode GE of the transistor TR may be disposed on the first insulation layer 112. The gate electrode GE may include a conductive material and, for example, may include a single layer or a multilayer, including one or more materials among molybdenum (Mo), copper (Cu), titanium (Ti), aluminum (Al), chromium (Cr), gold (Au), nickel (Ni), and neodymium (Nd), or an alloy thereof. The gate electrode GE may be formed on the first insulation layer 112 to overlap a channel region of the active layer ACT of the transistor TR. For example, the first insulation layer 112 may be disposed only between the gate electrode GE and the channel region of the active layer ACT.

A second insulation layer 113 may be disposed on the first insulation layer 112 and the gate electrode GE. The second insulation layer 113 may include an inorganic material and, for example, may include a single layer, including nitride silicon (SiNx) or oxide silicon (SiOx), or a multilayer thereof. Contact holes for respectively exposing the source region and the drain region of the active layer ACT of the transistor TR may be formed at the second insulation layer 113.

The source electrode SE and the drain electrode DE of the transistor TR may be disposed on the second insulation layer 113. The source electrode SE and the drain electrode DE of the transistor TR may be connected with the active layer ACT of the transistor TR through the contact holes formed at the first insulation layer 112 and the second insulation layer 113. Therefore, the source electrode SE of the transistor TR may be connected with the source region of the active layer ACT through a contact hole formed at the first insulation layer 112 and the second insulation layer 113. In addition, the drain electrode DE of the transistor TR may be connected with the drain region of the active layer ACT through another contact hole formed at the first insulation layer 112 and the second insulation layer 113.

The source electrode SE and the drain electrode DE may include a conductive material and, for example, may include a single layer or a multilayer including one or more materials among molybdenum (Mo), copper (Cu), titanium (Ti), aluminum (Al), chromium (Cr), gold (Au), nickel (Ni), and neodymium (Nd), or an alloy thereof. For example, the source electrode SE and the drain electrode DE may include a conductive material which is the same as or different from that of the gate electrode GE.

A passivation layer 114 may be disposed on the source electrode SE and the drain electrode DE of the transistor TR. For example, the passivation layer 114 may be disposed to cover a plurality of transistors TR. The passivation layer 114 may include an inorganic material and, for example, may include a single layer, including nitride silicon (SiNx) or oxide silicon (SiOx), or a multilayer thereof. A contact hole for exposing the source electrode SE and/or the drain electrode DE of the transistor TR may be formed at the passivation layer 114. For example, the passivation layer 114 may be a third insulation layer or an inorganic insulation layer.

A first planarization layer 115 may be disposed on the passivation layer 114. A contact hole for exposing the drain electrode DE (or the source electrode SE) may be formed at the first planarization layer 115. The first planarization layer 115 may include an organic material layer for planarizing and protecting an upper portion of the transistor TR. For example, the first planarization layer 115 may include an organic material, such as acrylic resin, epoxy resin, phenol resin, polyamide resin, polyimide resin, or the like, but embodiments of the present disclosure are not limited thereto. For example, the first planarization layer 115 may be an overcoat layer, a lower overcoat layer, a first overcoat layer, a fourth insulation layer, or a first protection layer.

A connection electrode 120 may be disposed on the first planarization layer 115. The connection electrode 120 may be connected with the drain electrode DE (or the source electrode SE) of the transistor TR through the contact hole in the first planarization layer 115. The connection electrode 120 may serve to electrically connect the transistor TR with the first electrode 131 of the light emitting device 130. The connection electrode 120 may include a single layer or a multilayer including one or more materials among molybdenum (Mo), copper (Cu), titanium (Ti), aluminum (Al), chromium (Cr), gold (Au), nickel (Ni), and neodymium (Nd), or an alloy thereof, but embodiments of the present disclosure are not limited thereto. The connection electrode 120 may include a material which is the same as or different from that of the source electrode SE and the drain electrode DE of the transistor TR.

According to example embodiments of the present disclosure, a signal line for driving a pixel may be additionally provided at the first planarization layer 115. For example, the signal line may be formed of the same material as that of the connection electrode 120 through the same process as the connection electrode 120, but embodiments of the present disclosure are not limited thereto.

A second planarization layer 116 may be disposed on the first planarization layer 115 and the connection electrode 120. A contact hole for exposing the connection electrode 120 may be formed in the second planarization layer 116. The second planarization layer 116 may be an organic material layer for planarizing the upper portion of the transistor TR. For example, the second planarization layer 116 may include an organic material, such as acrylic resin, epoxy resin, phenol resin, polyamide resin, polyimide resin, or the like, but embodiments of the present disclosure are not limited thereto. For example, the second planarization layer 116 may include an organic material which is the same as or different from that of the first planarization layer 115. For example, the second planarization layer 116 may be an upper overcoat layer, a second overcoat layer, a fifth insulation layer, or a second protection layer.

The light emitting device 130 may be disposed on the second planarization layer 116. The light emitting device 130 may include a first electrode 131, an emission structure (or a light emitting structure) 132, and a second electrode 133.

The first electrode 131 may be disposed on the second planarization layer 116. The first electrode 131 may be electrically connected with the connection electrode 120 through the contact hole formed at the second planarization layer 116. Accordingly, the first electrode 131 may be connected with the connection electrode 120 through the contact hole formed in the second planarization layer 116 and thus may be electrically connected with the transistor TR.

The first electrode 131 may be an anode electrode (or a cathode electrode). For example, where the display apparatus 100 according to an example embodiment of the present disclosure has a top emission structure, the first electrode 131 may be a reflection electrode which reflects light incident from the emission structure 132. As another example, where the example display apparatus 100 has a bottom emission structure, the first electrode 131 may be a transparent electrode which transmits the light incident from the emission structure 132.

A bank 117 may be disposed on the first electrode 131 and the second planarization layer 116. An opening portion (or an emission area) for exposing a portion of the first electrode 131 may be formed at the bank 117. For example, the bank 117 may be disposed on the second planarization layer 116 to cover only a periphery portion of the first electrode 131. The bank 117 may define an emission area of the display apparatus 100 (or a subpixel). For example, the bank 117 may be a bank layer, a bank pattern, a pixel defining layer, or a pixel defining pattern, but embodiments of the present disclosure are not limited thereto.

A bank projection 117s may be disposed on the bank 117. The bank projection 117s may protrude from the bank 117, or may include a material which differs from that of the bank 117 and may be disposed on the bank 117. The bank projection 117s may be configured to support a mask for formation of the emission structure 132, but embodiments of the present disclosure are not limited thereto.

The emission structure 132 including the light emitting layer may be further disposed on the first electrode 131. The emission structure 132 may be formed by stacking a hole layer, a light emitting layer, and an electron layer on the first electrode 131 in the order thereof or in the reverse order thereof. Furthermore, the emission structure 132 may include first and second emission structures which are opposite to each other with a charge generating layer therebetween. For example, the light emitting layer of one of the first and second emission structures may generate first color light (or blue light) and the light emitting layer of the other of the first and second emission structures may generate second color light (or yellow light or yellow light and green light). Thus, white light may be generated based on the first color light and the second color light of the first and second emission structures. The white light generated by the emission structure 132 may be incident on a color filter disposed on the emission structure 132 to implement a color image. Furthermore, without a separate color filter, each emission structure 132 may generate color light corresponding to each subpixel to implement a color image. For example, an emission structure 132 of a red subpixel may generate red light, an emission structure 132 of a green subpixel may generate green light, and an emission structure 132 of a blue subpixel may generate blue light.

The second electrode 133 may be further disposed on the emission structure 132. The second electrode 133 may be disposed on the emission structure 132 so that the emission structure 132 is between the first electrode 131 and the second electrode 133.

In the display apparatus 100 according to an example embodiment of the present disclosure, the second electrode 133 may be a cathode electrode (or an anode electrode). For example, where the display apparatus 100 according to an example embodiment of the present disclosure has the top emission structure, the second electrode 133 may be a transparent electrode which transmits the light incident from the emission structure 132. As another example, where the display apparatus 100 has the bottom emission structure, the second electrode 133 may be a reflection electrode which reflects the light incident from the emission structure 132.

The encapsulation portion 140 may be disposed on the light emitting device 130. For example, the encapsulation portion 140 which prevents the penetration of water may be further disposed on the second electrode 133.

The encapsulation portion 140 may include one or more encapsulation layers. For example, the encapsulation portion 140 may include one or more inorganic encapsulation layers on the light emitting device 130 and one or more organic encapsulation layers on the light emitting device 130. For example, the encapsulation portion 140 may include a first encapsulation layer 141, a second encapsulation layer 142, and a third encapsulation layer 143.

The first encapsulation layer 141 of the encapsulation portion 140 may be disposed on the second electrode 133. The second encapsulation layer 142 may be disposed on the second electrode 133 or the first encapsulation layer 141. In addition, the third encapsulation layer 143 may be disposed on the second electrode 133 or the second encapsulation layer 142. The first encapsulation layer 141 and the third encapsulation layer 143 of the encapsulation portion 140 may include an inorganic material, such as nitride silicon (SiNx) or oxide silicon (SiOx), or the like, but the embodiments of the present disclosure are not limited thereto. The second encapsulation layer 142 of the encapsulation portion 140 may include an organic material, such as acrylic resin, epoxy resin, phenol resin, polyamide resin, polyimide resin, or the like, but embodiments of the present disclosure are not limited thereto.

The display apparatus 100 or the display area A/A of the display apparatus 100 according to an example embodiment of the present disclosure may further include a touch sensing portion 160.

The touch sensing portion 160 may be disposed on the encapsulation portion 140. The touch sensing portion 160 may be disposed on the third encapsulation layer 143 of the encapsulation portion 140.

A touch insulation layer 150 may be further disposed between the encapsulation portion 140 and the touch sensing portion 160. The touch insulation layer 150 may be disposed on the encapsulation portion 140. For example, the touch insulation layer 150 may be disposed on the third encapsulation layer 143 of the encapsulation portion 140. For example, the touch insulation layer 150 may be a touch buffer layer, a first touch interlayer insulation layer, or a sixth insulation layer. The touch insulation layer 150 may include an inorganic material, such as nitride silicon (SiNx) or oxide silicon (SiOx), or the like, but the embodiments of the present disclosure are not limited thereto

The touch sensing portion 160 may be disposed on the touch insulation layer 150. The touch sensing portion 160 may include a first touch electrode layer 161, an interlayer insulation layer 163, and a second touch electrode layer 165.

The first touch electrode layer 161 may include a plurality of first touch electrodes TE1 disposed on the touch insulation layer 150. The plurality of first touch electrodes TE1 may include transparent metal or may include opaque metal. For example, the plurality of first touch electrodes TE1 may include a plurality of bridge electrodes or a plurality of bridge lines.

The interlayer insulation layer 163 may be disposed on the encapsulation portion 140 or the touch insulation layer 150 to cover the first touch electrode layer 161. For example, the interlayer insulation layer 163 may be disposed on the touch insulation layer 150 to cover the first touch electrode layer 161. the interlayer insulation layer 163 may include a via hole which exposes at least a portion of a corresponding one of the plurality of first touch electrodes TEL The interlayer insulation layer 163 may include an inorganic material, such as nitride silicon (SiNx) or oxide silicon (SiOx), or the like, but the embodiments of the present disclosure are not limited thereto. The interlayer insulation layer 163 may be a second touch interlayer insulation layer or a seventh insulation layer.

The second touch electrode layer 165 may include a plurality of second touch electrodes TE2 disposed on the interlayer insulation layer 163 or the first touch electrode TEL The plurality of second touch electrodes TE2 may include transparent metal or may include opaque metal. For example, the plurality of second touch electrodes TE2 may include a mesh structure. For example, the plurality of second touch electrodes TE2 may be a plurality of touch sensing electrodes or a plurality of touch driving electrodes, but the embodiments of the present disclosure are not limited thereto.

In the second touch electrode layer 165, each of the plurality of second touch electrodes TE2 arranged adjacent to one another in a first direction X or a second direction Y may be connected with a corresponding first touch electrode TE1 of the plurality of first touch electrodes TE1 through a via hole formed at the interlayer insulation layer 163. Therefore, the plurality of second touch electrodes TE2 arranged adjacent to one another in the first direction X or the second direction Y may be connected with one another through the plurality of first touch electrodes TE1. For example, the plurality of second touch electrodes TE2 arranged adjacent to one another in the second direction Y may be connected with one another through the plurality of first touch electrodes TE1.

According to an example embodiment of the present disclosure, the plurality of first touch electrodes TE1 may be disposed on the first touch insulation layer 150, and the interlayer insulation layer 163 may be disposed on the plurality of first touch electrodes TEL In addition, the plurality of second touch electrodes TE2 may be disposed on the interlayer insulation layer 163 or respectively on the plurality of first touch electrode TEL The plurality of second touch electrodes TE2 may be connected with the plurality of first touch electrodes TE1, respectively, through one or more via holes included at the interlayer insulation layer 163.

The display apparatus 100 or the display area A/A of the display apparatus 100 according to an example embodiment of the present disclosure may further include a third planarization layer 170. The third planarization layer 170 may be disposed on the touch sensing portion 160. The third planarization layer 170 may be configured to cover or surround the touch sensing portion 160. The third planarization layer 170 may be disposed on the interlayer insulation layer 163 to cover the second touch electrode layer 165. For example, the third planarization layer 170 may include an organic material, such as acrylic resin, epoxy resin, phenol resin, polyamide resin, polyimide resin, or the like, but embodiments of the present disclosure are not limited thereto. For example, the third planarization layer 170 may include an organic material which is the same as or different from that of the first planarization layer 115 or the second planarization layer 116. For example, the third planarization layer 170 may be a third overcoat layer, an eighth insulation layer, a touch protection layer, or a third protection layer.

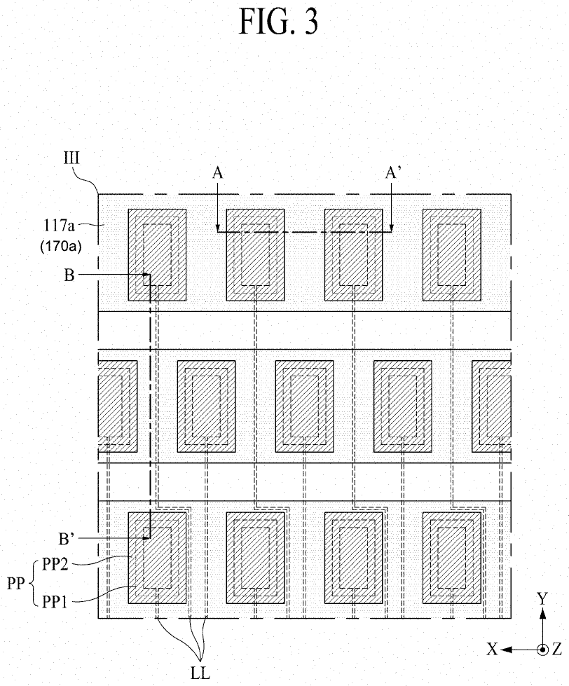

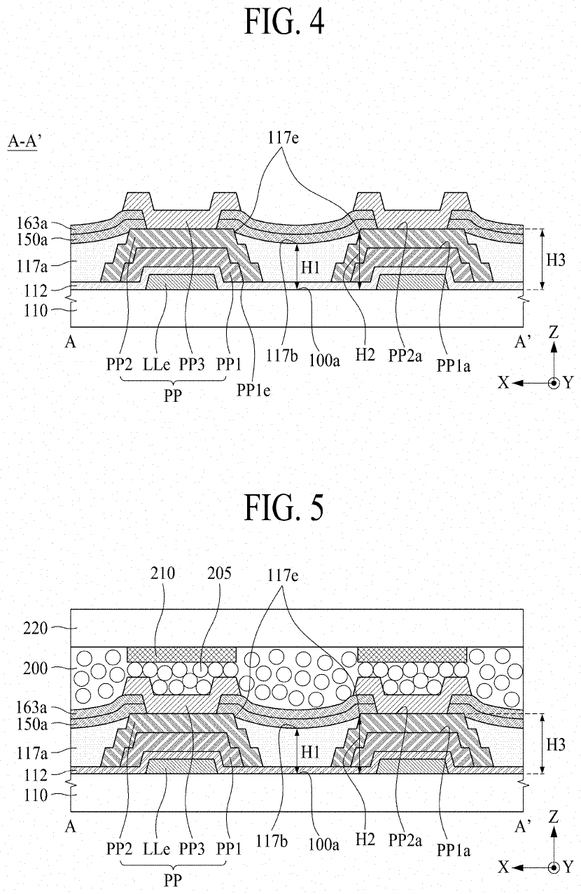

FIG. 3 is an example of an enlarged view of a region III of FIG. 1. FIG. 4 is an example cross-sectional view taken along line A-A′ of FIG. 3.

As shown in FIGS. 1 to 4, a pad area PA according to an example embodiment of the present disclosure may include a plurality of pads PP, a plurality of link lines LL, and a pad insulation layer 117a.

According to an example embodiment of the present disclosure, the plurality of pads PP may be disposed at the plurality of link lines LL in the pad area PA. The plurality of link lines LL may be a signal line. The plurality of pads PP may extend toward the non-display area N/A from the display area A/A and may be connected with the plurality of link lines LL. The plurality of pads PP may include a first pad pattern PP1 and a second pad pattern PP2. At least one of the first pad pattern PP1 and the second pad pattern PP2 may be connected with a corresponding link line LL of the plurality of link lines LL. The second pad pattern PP2 may cover the first pad pattern PP1.

As illustrated in FIG. 3, the plurality of pads PP may be arranged at a certain interval along each of the first direction X and the second direction Y intersecting with the first direction X. The plurality of pads PP may be arranged in three columns parallel to the first direction X, but embodiments of the present disclosure are not limited thereto. The plurality of pads PP arranged in three columns may be staggered with respect to one another. For example, a plurality of pads PP arranged in a second column may be arranged between a plurality of pads PP arranged in a first column and a third column. Accordingly, because the plurality of pads PP are arranged to be staggered, a size of the pad area PA may be reduced.

The pad insulation layer 117a may be disposed between the plurality of pads PP along the first direction X. The pad insulation layer 117a may include a plurality of insulation patterns which respectively surround the plurality of pads PP. The plurality of insulation patterns may be spaced apart from one another between two pads PP adjacent to each other along the second direction Y. The pad insulation layer 117a may be an insulation layer in the pad area PA. The pad insulation layer 117a may be an insulation layer or a pad insulation pattern, but embodiments of the present disclosure are not limited to those terms.

As illustrated in FIGS. 2 to 4, the pad insulation layer 117a may be disposed between the plurality of pads PP.

According to an example embodiment of the present disclosure, each of the plurality of pads PP may include a link line extension portion LLe, the first insulation layer 112, the first pad pattern PP1, and the second pad pattern PP2. At least some of elements included in a pad PP according to an example embodiment of the present disclosure may be omitted, or another element may be added.

The link line extension portion LLe on the substrate 110 may be formed at an end (or a periphery portion) of the link line LL on the substrate 110. The link line extension portion LLe may enlarge or extend from the end (or the periphery portion) of the link line LL to have a width which is relatively greater than that of the link line LL. For example, the link line extension portion LLe may include the same gate electrode material for forming the gate electrode GE and may be formed along with the gate electrode GE through a patterning process performed on the gate electrode material. The first insulation layer 112 may be disposed on the link line extension portion LLe. Thus, the link line extension portion LLe may be covered by the first insulation layer 112.

The first pad pattern PP1 and the second pad pattern PP2 overlapping the link line extension portion LLe may be sequentially stacked on the first insulation layer 112. The first pad pattern PP1 may be disposed on the link line extension portion LLe with the first insulation layer 112 therebetween and may cover the link line extension portion LLe. The second pad pattern PP2 may be disposed on the first pad pattern PP1 to surround the first pad pattern PP1. The second pad pattern PP2 may directly contact the first pad pattern PP1 and may directly cover an upper surface and lateral surfaces of the first pad pattern PP1.

One or more of the first pad pattern PP1 and the second pad pattern PP2 may include the same material as that of the source electrode SE (or the drain electrode DE) of the transistor TR. For example, the first pad pattern PP1 may include the same material as that of the source electrode SE (or the drain electrode DE), and the second pad pattern PP2 may include the same material as that of the connection electrode 120 disposed in the display area A/A. For example, the first pad pattern PP1 may include the same source/drain electrode material for forming the source electrode SE (or the drain electrode DE) of the transistor TR and may be formed along with the source/drain electrode SE/DE through a patterning process performed on the source/drain electrode material, but embodiments of the present disclosure are not limited thereto. For example, the second pad pattern PP2 may include the same connection electrode material for forming the connection electrode 120 disposed in the display area A/A and may be formed along with the connection electrode 120 through a patterning process performed on the connection electrode material, but embodiments of the present disclosure are not limited thereto.

In FIG. 4, an example is illustrated where a plurality of metal layers (for example, the first pad pattern PP1 and the second pad pattern PP2) overlapping the link line extension portion LLe are disposed on the first insulation layer 112. However, embodiments of the present disclosure are not limited thereto, and only one of the first pad pattern PP1 and the second pad pattern PP2 may be disposed or another metal layer may be further disposed.

The pad insulation layer (or the first pad insulation layer) 117a may be disposed at a periphery of the first pad pattern PP1 and the second pad pattern PP2. The pad insulation layer 117a may include the same material as that of the bank 117 of the display area A/A. The pad insulation layer 117a may be disposed in the pad area PA of the substrate 110 corresponding to a region between the plurality of pads PP. The pad insulation layer 117a may be disposed on the first insulation layer 112 of the pad area PA corresponding to a region between the plurality of pads PP. For example, the pad insulation layer 117a may include a plurality of insulation patterns respectively surrounding the plurality of pads PP. The plurality of insulation patterns may be spaced apart from each other between two pads PP adjacent to each other along the second direction Y.

A periphery portion of the pad insulation layer 117a may cover a periphery portion of the first pad pattern PP1 or the second pad pattern PP2. For example, the periphery portion of the pad insulation layer 117a may cover a lateral surface of the first pad pattern PP1 or the second pad pattern PP2. For example, the periphery portion of the pad insulation layer 117a may cover the periphery portion (or the lateral surface) of the second pad pattern PP2 except an uppermost surface (or an uppermost flat surface) PP2a of the second pad pattern PP2, or may contact or directly contact the periphery portion (or the lateral surface) of the second pad pattern PP2. For example, the uppermost surface (or the uppermost flat surface) PP2a of the second pad pattern PP2 except the periphery portion (or the lateral surface) of the second pad pattern PP2 may not overlap the pad insulation layer 117a or may not be covered by the pad insulation layer 117a. For example, both ends 117e of the pad insulation layer 117a disposed between two adjacent pads PP may not overlap an uppermost surface (or an uppermost flat surface) PP1a of the first pad pattern PP1. For example, both ends 117e of the pad insulation layer 117a disposed between two adjacent pads PP may be disposed or located at the periphery portion (or the lateral surface) of the second pad pattern PP2 overlapping a region between the uppermost surface (or the uppermost flat surface) PP1a and an end PP1e of the first pad pattern PP1.

According to an example embodiment of the present disclosure, a first distance H1 between the substrate 110 and a center portion 117b of the pad insulation layer 117a may be smaller than a second distance H2 between the substrate 110 and the periphery portion (or the end) 117e of the pad insulation layer 117a. For example, the first distance (or a first shortest distance) H1 between a first surface (or an upper surface) 100a of the substrate 110 and the center portion 117b of the pad insulation layer 117a may be smaller than the second distance (or a second shortest distance) H2 between both ends 117e of the pad insulation layer 117a and the first surface (or the upper surface) 100a of the substrate 110.

According to another example embodiment of the present disclosure, the first distance H1 may be less than or equal to a third distance H3 between the substrate 110 and the uppermost surface PP2a of the second pad pattern PP2. For example, the first distance H1 may be less than or equal to the third distance H3 between the uppermost surface PP2a of the second pad pattern PP2 and the first surface (or the upper surface) 100a of the substrate 110. For example, the second distance H2 may be less than or equal to the third distance H3. For example, the second distance H2 may be greater than or equal to the first distance H1 and may be less than or equal to the third distance H3.

According to another example embodiment of the present disclosure, a thickness of the pad insulation layer 117a may decrease progressively toward the center portion 117b from both ends 117e thereof. Accordingly, an upper surface (or a top surface) of the pad insulation layer 117a may include a non-flat structure. For example, the upper surface (or the top surface) of the pad insulation layer 117a may be concave or may include a concave curved structure.

The pad area PA according to an example embodiment of the present disclosure may further include one or more second pad insulation layers 150a and 163a.

The one or more second pad insulation layers 150a and 163a may be disposed between the plurality of pads PP to cover the pad insulation layer 117a. For example, the one or more second pad insulation layers 150a and 163a may be disposed between the plurality of pads PP along the first direction X and may be configured to cover or fully cover the pad insulation layer 117a. For example, a periphery portion of each of the plurality of pads PP may be covered by periphery portions of the one or more second pad insulation layers 150a and 163a. For example, a periphery portion of the uppermost surface (or the uppermost flat surface) PP1 a of each of the plurality of pads PP may be covered by periphery portions of the one or more second pad insulation layers 150a and 163a. For example, the periphery portions of the one or more second pad insulation layers 150a and 163a may contact or directly contact a periphery portion of an uppermost surface (or an uppermost flat surface) PP2a of each of the plurality of pads PP. For example, the one or more second pad insulation layers 150a and 163a may cover a periphery portion of the second pad pattern PP2 and the pad insulation layer 117a. For example, the periphery portions of the one or more second pad insulation layers 150a and 163a may contact or directly contact a periphery portion of an uppermost surface (or an uppermost flat surface) PP2a of the second pad pattern PP2. For example, the one or more second pad insulation layers 150a and 163a may cover a boundary portion between the second pad pattern PP2 and the pad insulation layer 117a. Accordingly, the pad insulation layer 117a may be surrounded or sealed by the first insulation layer 112, two adjacent second pad patterns PP2, and the one or more second pad insulation layers 150a and 163a.

According to an example embodiment of the present disclosure, the one or more second pad insulation layers 150a and 163a may include one or more of a lower insulation layer 150a and an upper insulation layer 163a.

The lower insulation layer 150a may include the same material as that of the touch insulation layer 150 disposed at the display area A/A. The lower insulation layer 150a may cover the periphery portion of the second pad pattern PP2 and the pad insulation layer 117a. For example, a periphery portion of the lower insulation layer 150a may contact or directly contact the periphery portion of the uppermost surface (or the uppermost flat surface) PP2a of the second pad pattern PP2. For example, the lower insulation layer 150a may cover the boundary portion between the second pad pattern PP2 and the pad insulation layer 117a.

The upper insulation layer 163a may be disposed on the lower insulation layer 150a. For example, the upper insulation layer 163a may contact or directly contact the lower insulation layer 150a. The upper insulation layer 163a may include the same material as that of the interlayer insulation layer 163 disposed at the display area A/A.

The pad area PA or each of the plurality of pads PP according to an example embodiment of the present disclosure may further include a third pad pattern PP3.

The third pad pattern PP3 may be connected with the second pad pattern PP2 and may be configured to cover the periphery portions of the one or more second pad insulation layers 150a and 163a. For example, the third pad pattern PP3 may contact or directly contact the second pad pattern PP2 and may contact or directly contact the periphery portions of the one or more second pad insulation layers 150a and 163a. For example, a center portion of the third pad pattern PP3 may contact or directly contact the uppermost surface (or the uppermost flat surface) PP2a of the second pad pattern PP2. For example, a periphery portion of the third pad pattern PP3 may contact or directly contact the periphery portions of the one or more second pad insulation layers 150a and 163a. For example, the periphery portions of the one or more second pad insulation layers 150a and 163a may be disposed or interposed between the second pad pattern PP2 and the third pad pattern PP3. For example, the periphery portions of the one or more second pad insulation layers 150a and 163a may be disposed or interposed between the periphery portion of the uppermost surface (or the uppermost flat surface) PP2a of the second pad pattern PP2 and the periphery portion of the third pad pattern PP3.

The third pad pattern PP3 may include the same material as that of any one of the first touch electrode layer 161 and the second touch electrode layer 165 of the touch sensing portion 160 in the display area A/A. The third pad pattern PP3 may include the same material as that of the plurality of second touch electrodes TE2 disposed in the display area A/A.

The third pad pattern PP3 may include a touch electrode material for forming the plurality of second touch electrodes TE2 and may be formed along with the plurality of second touch electrodes TE2 through a patterning process performed on the touch electrode material, but embodiments of the present disclosure are not limited thereto. For example, the third pad pattern PP3 may include an opaque metal, but embodiments of the present disclosure are not limited thereto.

FIG. 5 is a diagram for describing another example of a cross-sectional surface taken along line A-A′ of FIG. 3. FIG. 5 is a diagram for describing a connection structure between a pad and a driving circuit disposed in a circuit disposition area 180 of a substrate in a display apparatus according to an example embodiment of the present disclosure.

As illustrated in FIG. 5, an input bump which receives image data and an output bump which outputs the image data to a display panel may be disposed in a driving circuit 220. A bump 210 may correspond to the output bump (or a terminal) in FIG. 5 but may be applied to the input bump. The bump 210 may be connected with a plurality of pads PP through an adhesive member 200. The adhesive member 200 may be disposed or interposed between the bump 210 and the plurality of pads PP. The adhesive member 200 may be disposed or interposed between the driving circuit 220 and each of one or more second pad insulation layers 150a and 163a and the plurality of pads PP. For example, the adhesive member 200 may be disposed or interposed between the driving circuit 220 and each of the one or more second pad insulation layers 150a and 163a and a third pad pattern PP3 of each of the plurality of pads PP. The adhesive member 200 may include an adhesive material and a conductive material. For example, the adhesive member 200 may include an anisotropic conductive film. The anisotropic conductive film may be a thin film having an adhesive resin component including conductive particles 205 so as to have vertically electrical conduction (conduction properties) and an adhesive force. The conductive particles 205 may include a plurality of small metal particles or a plurality of small conductive balls for transferring a signal in the adhesive member 200. The anisotropic conductive film may allow a current to flow because conductive particles are dispersed therein and may maintain an adhesive force because adhesive resin is cured by heat and pressure. For example, conductive particles 205 between the bump 210 and the pad PP may contact or physically and directly contact one another. Thus, the conductive particles 205 may be electrically connected with each of the bump 210 and the pad PP.

As shown in FIGS. 1, 3, and 5, the bump 210 of the driving circuit 220 may be electrically connected or electrically and directly connected with a third pad pattern PP3 of the pad PP through the conductive particle 205 of the adhesive member 200. In this case, a signal generated by the driving circuit 220 may be transferred to the link line LL via the bump 210, the third pad pattern PP3, a second pad pattern PP2, and a first pad pattern PP1 and may be transferred to a pixel through the link line LL.

When heat and pressure are applied for attaching the driving circuit 220 on the circuit disposition area 180 of the display panel, or in an environment where a temperature condition is high, the adhesive member 200 may repeat a volume variation (or expansion) based on a temperature variation and the volume variation (or contraction) in a process (spring back) which returns to a room temperature. Thus, a driving defect may occur due to an interlayer stripping phenomenon caused by stress accumulated in the pad insulation layer 117a. Where a thickness of an insulation layer between adjacent pads PP is large, a peripheral layer may be much affected by the volume variation (or contraction) of the adhesive member 200. As a result, a partial detachment (or a layer-lifting phenomenon) of an inter-interface layer between the second pad pattern PP2 and the pad insulation layer 117a may occur. Therefore, an uppermost surface PP2a of the second pad pattern PP2 may be disposed or configured more upward than a periphery portion (or both ends) 117e of the pad insulation layer 117a to minimize an adverse effect of the pad insulation layer 117a caused by a volume variation of the adhesive member 200 while protecting the second pad pattern PP2 and to decrease the volume and/or accumulated stress of the pad insulation layer 117a. A first distance H1 between a substrate 110 and a center portion 117b of the pad insulation layer 117a may be a thickness up to an upper surface 117b of the pad insulation layer 117a from an upper surface 100a of the substrate 110 and may be smaller than a third distance H3 up to an uppermost surface PP2a of the second pad pattern PP2 from the upper surface 100a of the substrate 110. A second distance H2 between the end 117e of the pad insulation layer 117a and the substrate 110 may be greater than or equal to the first distance H1 between the substrate 110 and the center portion 117b of the pad insulation layer 117a. And the second distance H2 may be less than or equal to the third distance H3 up to the uppermost surface PP2a of the second pad pattern PP2 from the upper surface 100a of the substrate 110.

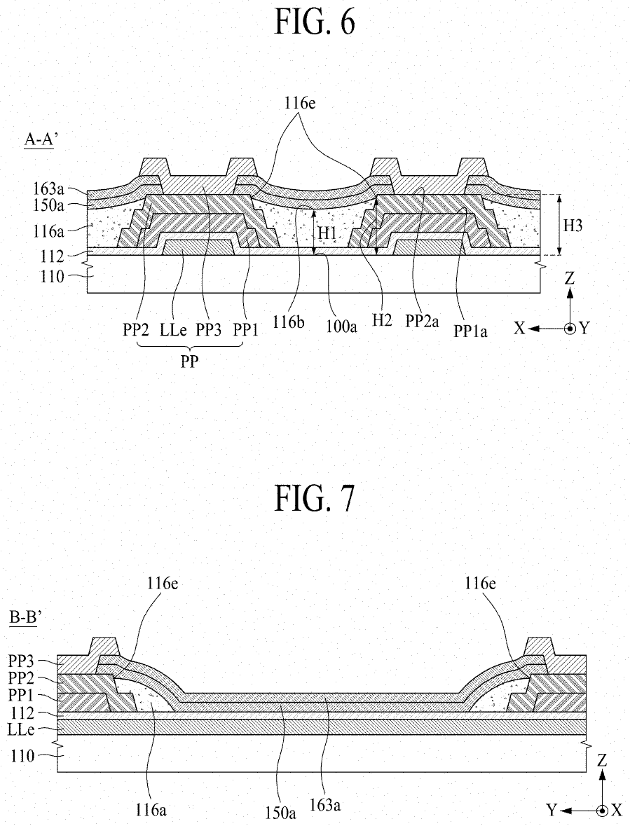

FIG. 6 is another example cross-sectional view taken along line A-A′ of FIG. 3. FIG. 7 is an example cross-sectional view taken along line B-B′ of FIG. 3. FIGS. 6 and 7 illustrate an example embodiment implemented by changing a material of the pad insulation layer illustrated in FIGS. 3 to 5. Therefore, in the following description, descriptions of the elements other than a pad insulation layer and elements relevant thereto may be omitted or briefly given.

As shown in FIGS. 2, 3, 6, and 7, in an example embodiment of present disclosure, each pads PP may include at least one of the link line extension portion LLe, the first insulation layer 112, the first pad pattern PP1, the second pad pattern PP2, and the third pad pattern PP3, which are on the substrate 110. At least some of elements included in a pad PP according to an example embodiment of the present disclosure may be omitted, or another element may be added.

The link line extension portion LLe on the substrate 110 may be formed at an end (or a periphery portion) of the link line LL. The link line extension portion LLe may include the same material as that of the gate electrode GE. The substrate 110 may correspond to the substrate 110 of FIG. 1. For example, the substrate 110 may be a portion, disposed at the pad area PA, of the substrate 110 of FIG. 1. The link line extension portion LLe may include the same material as that of the gate electrode GE of the transistor TR disposed at the display area A/A.

The first insulation layer 112 may be disposed on the link line extension portion LLe. Accordingly, the link line extension portion LLe may be covered by the first insulation layer 112.

The first pad pattern PP1 and the second pad pattern PP2 of the pad PP overlapping the link line extension portion LLe may be sequentially stacked on the first insulation layer 112. The third pad pattern PP3 of the pad PP may be additionally stacked on the first insulation layer 112. The first pad pattern PP1, the second pad pattern PP2, and the third pad pattern PP3 may be as described above with reference to FIGS. 3 to 5. Thus, repetitive descriptions thereof are omitted.

The pad insulation layer 116a disposed between the plurality of pads PP may include the same material as that of the first planarization layer 115 or the second planarization layer 116. For example, the pad insulation layer 116a may include the same material as that of the second planarization layer 116 of the display area A/A.

The pad insulation layer 116a may be disposed at a periphery (or a peripheral area) of each of the plurality of pads PP.

The pad insulation layer 116a may be disposed between the plurality of pads PP along the first direction X. For example, the pad insulation layer 116a may be disposed on the first insulation layer 112 between the plurality of pads PP along the first direction X. For example, the pad insulation layer 116a may be disposed at a whole region between two adjacent pads PP of the plurality of pads PP along the first direction X and may cover a periphery portion of each of two adjacent pads PP.

The pad insulation layer 116a may be disposed between the plurality of pads PP along the second direction Y. The pad insulation layer 116a may be disposed on the first insulation layer 112 between the plurality of pads PP along the second direction Y. The pad insulation layer 116a may be disposed between the plurality of pads PP along the second direction Y and may have portions spaced apart from one another along the second direction Y. For example, the pad insulation layer 116a may be disposed between two adjacent pads PP of the plurality of pads PP along the second direction Y and may be disposed to cover a periphery portion of each of two adjacent pads PP along the second direction Y. For example, the pad insulation layer 116a may be disposed at each of an upper (or left) periphery region and a lower (or right) periphery region, except a center region, of a region between two adjacent pads PP along the second direction Y. Thus, the pad insulation layer 116a may be disposed to cover the periphery portion of each of two adjacent pads PP along the second direction Y.

The pad insulation layer 116a may have portions spaced apart from one another or arranged at a certain interval along the second direction Y. The pad insulation layer 116a may have portions spaced apart from one another along the second direction Y and may be disposed at each line parallel to the first direction X. The pad insulation layer 116a may have portions apart from one another in the second direction Y and may be disposed to surround each of the plurality of pads PP in each line parallel to the first direction X. For example, the pad insulation layer 116a may include a plurality of insulation patterns respectively surrounding the plurality of pads PP. The plurality of insulation patterns may be disposed in a line shape to respectively surround the plurality of pads PP arranged along the first direction X and may be spaced apart from one another along the second direction Y.

Because the pad insulation layer 116a is not disposed or formed where a pad is not disposed (or provided) in a region between two adjacent pads PP along the second direction Y, a volume or accumulated stress may decrease. Thus, stress applied to the pad insulation layer 116a by a volume variation of the adhesive member 200, as described above with reference to FIG. 5, may be minimized or reduced, thereby preventing or minimizing the partial detachment (or a layer-lifting phenomenon) and/or stripping (or a peeling phenomenon) of a layer at an interface between the pad PP and the pad insulation layer 116a.

According to an example embodiment of the present disclosure, a first distance H1 between the substrate 110 and a center portion 116b of the pad insulation layer 116a may be smaller than a second distance H2 between the substrate 110 and a periphery portion (or an end) 116e of the pad insulation layer 116a. For example, the first distance (or a first shortest distance) H1 between a first surface (or an upper surface) 100a of the substrate 110 and the center portion 116b of the pad insulation layer 116a may be smaller than the second distance (or a second shortest distance) H2 between both ends 116e of the pad insulation layer 116a and the first surface (or the upper surface) 100a of the substrate 110.

According to another example embodiment of the present disclosure, the first distance H1 may be less than or equal to a third distance H3 between the substrate 110 and an uppermost surface PP2a of the second pad pattern PP2. For example, the first distance H1 may be less than or equal to the third distance H3 between the uppermost surface PP2a of the second pad pattern PP2 and the first surface (or the upper surface) 100a of the substrate 110. For example, the second distance H2 may be less than or equal to the third distance H3. For example, the second distance H2 may be greater than or equal to the first distance H1 and may be less than or equal to the third distance H3.

According to another example embodiment of the present disclosure, a thickness of the pad insulation layer 116a may decrease progressively toward the center portion 116b from both ends 116e thereof. Accordingly, an upper surface (or a top surface) of the pad insulation layer 116a may include a non-flat structure. For example, the upper surface (or the top surface) of the pad insulation layer 116a may be concave or may include a concave curved structure.

One or more second pad insulation layers 150a and 163a may be disposed on the pad insulation layer 116a.

The one or more second pad insulation layers 150a and 163a may be disposed between the plurality of pads PP to cover the pad insulation layer 116a. For example, the one or more second pad insulation layers 150a and 163a may be disposed between the plurality of pads PP along the first direction X and may be configured to cover or fully cover the pad insulation layer 116a. For example, a periphery portion of each of the plurality of pads PP may be covered by periphery portions of the one or more second pad insulation layers 150a and 163a. For example, a periphery portion of the uppermost surface (or the uppermost flat surface) PP1a of each of the plurality of pads PP may be covered by periphery portions of the one or more second pad insulation layers 150a and 163a. For example, the periphery portions of the one or more second pad insulation layers 150a and 163a may contact or directly contact a periphery portion of an uppermost surface (or an uppermost flat surface) PP2a of each of the plurality of pads PP. For example, the one or more second pad insulation layers 150a and 163a may cover a periphery portion of the second pad pattern PP2 and the pad insulation layer 116a. For example, the periphery portions of the one or more second pad insulation layers 150a and 163a may contact or directly contact a periphery portion of an uppermost surface (or an uppermost flat surface) PP2a of the second pad pattern PP2. For example, the one or more second pad insulation layers 150a and 163a may cover a boundary portion between the second pad pattern PP2 and the pad insulation layer 116a. Accordingly, the pad insulation layer 116a may be surrounded or sealed by the first insulation layer 112, two adjacent second pad patterns PP2, and the one or more second pad insulation layers 150a and 163a.

According to an example embodiment of the present disclosure, the one or more second pad insulation layers 150a and 163a may include one or more of a lower insulation layer 150a and an upper insulation layer 163a.

The lower insulation layer 150a may include the same material as that of the touch insulation layer 150 disposed at the display area A/A. The lower insulation layer 150a may cover the periphery portion of the second pad pattern PP2 and the pad insulation layer 116a. For example, a periphery portion of the lower insulation layer 150a may contact or directly contact the periphery portion of the uppermost surface (or the uppermost flat surface) PP2a of the second pad pattern PP2. For example, the lower insulation layer 150a may cover the boundary portion between the second pad pattern PP2 and the pad insulation layer 116a.

The lower insulation layer 150a disposed between the plurality of pads PP along the first direction X may contact or directly contact the periphery portion of each of the pad insulation layer 116a and the plurality of pads PP.

The lower insulation layer 150a disposed between the plurality of pads PP along the second direction Y may be disposed to surround the pad insulation layer 116a and may contact or directly contact the periphery portion of each of the pad insulation layer 116a and the plurality of pads PP. The pad insulation layer 116a disposed between the plurality of pads PP along the second direction Y may be surrounded or sealed by the second pad pattern PP2, the first insulation layer 112, and the lower insulation layer 150a. For example, the lower insulation layer 150a disposed between the plurality of pads PP along the second direction Y may be disposed to surround the pad insulation layer 116a and may contact or directly contact the first insulation layer 112 at a middle region between the plurality of pads PP.

The upper insulation layer 163a may be disposed on the lower insulation layer 150a. For example, the upper insulation layer 163a may contact or directly contact the lower insulation layer 150a. The upper insulation layer 163a may include the same material as that of the interlayer insulation layer 163 disposed at the display area A/A.

The periphery portions of the one or more second pad insulation layers 150a and 163a may be disposed or interposed between the second pad pattern PP2 and the third pad pattern PP3. For example, the periphery portions of the one or more second pad insulation layers 150a and 163a may be disposed or interposed between the periphery portion of the uppermost surface (or the uppermost flat surface) PP2a of the second pad pattern PP2 and a periphery portion of the third pad pattern PP3.

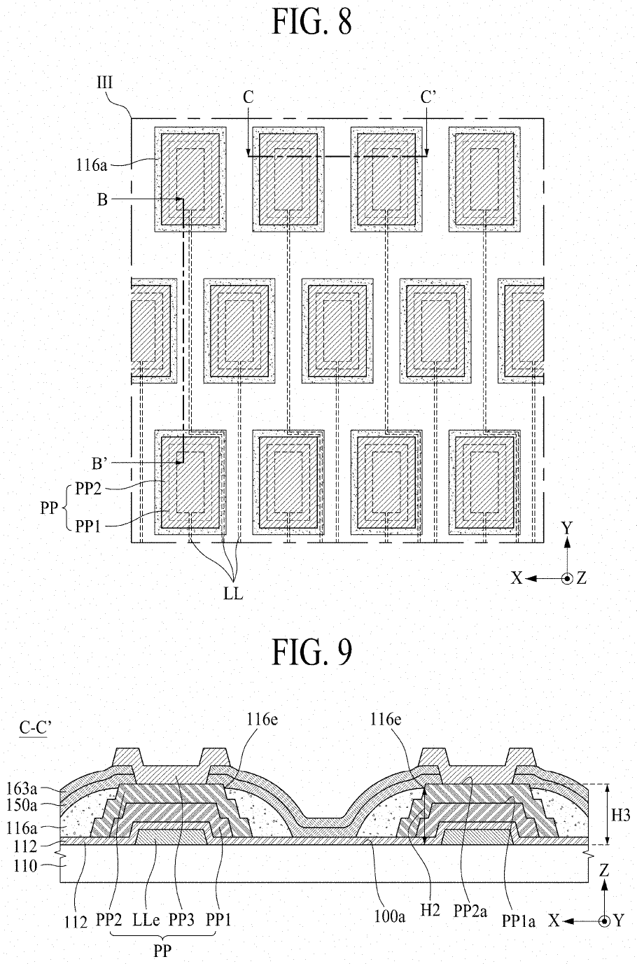

FIG. 8 is an example enlarged view of a region III of FIG. 1. FIG. 9 is an example cross-sectional view taken along line C-C′ of FIG. 8. FIGS. 8 and 9 illustrate an example embodiment implemented by modifying the shape and/or arrangement structure of the example pad insulation layer illustrated in FIGS. 1 to 7. Therefore, in the following description, descriptions of the elements other than a pad insulation layer and elements relevant thereto may be omitted or briefly given. FIG. 7 is an example cross-sectional view taken along line B-B′ of FIG. 8.

As illustrated in FIGS. 7 to 9, a plurality of pads PP may be arranged at a certain interval along each of a first direction X and a second direction Y intersecting with the first direction X.

A pad insulation layer 116a may be configured to surround a periphery portion of each of the plurality of pads PP. For example, the pad insulation layer 116a may be configured to individually surround the periphery portion of each of the plurality of pads PP. For example, the pad insulation layer 116a may include a plurality of insulation patterns which respectively surround the periphery portions of the plurality of pads PP. The plurality of insulation patterns may be spaced apart from one another between two adjacent pads PP along each of the first direction X and the second direction Y. The plurality of insulation patterns of the pad insulation layer 116a may be disposed in an island shape to respectively surround the periphery portions of the plurality of pads PP. For example, the plurality of insulation patterns may be disposed in an island shape to individually surround the periphery portions of the plurality of pads PP. For example, each of the plurality of insulation patterns may be formed in a tetragonal ring shape (or a tetragonal band) in a plan view and thus may cover or surround the periphery portion of one corresponding pad PP of the plurality of pads PP, but embodiments of the present disclosure are not limited thereto. For example, each of the plurality of insulation patterns may have a circular ring shape or an oval ring shape in a plan view.

An end 116e of the pad insulation layer 116a or an end 116e of each of the plurality of insulation patterns of the pad insulation layer 116a may be disposed or configured more downward than an uppermost surface PP2a of a second pad pattern PP2. Therefore, a second distance H2 between a substrate 110 and the end 116e of the pad insulation layer 116a or the end 116e of each of the plurality of insulation patterns of the pad insulation layer 116a may be smaller than a third distance H3 between the uppermost surface PP2a of the second pad pattern PP2 and the substrate 110. For example, the second distance H2 between the substrate 110 and an uppermost surface 116e of the pad insulation layer 116a or an uppermost surface 116e of each of the plurality of insulation patterns of the pad insulation layer 116a may be smaller than the third distance H3 between the uppermost surface PP2a of the second pad pattern PP2 and the substrate 110. Therefore, as described above with reference to FIG. 5, stress applied to the pad insulation layer 116a by a volume variation of the adhesive member 200 may be minimized or reduced, thereby preventing or minimizing the partial detachment (or a layer-lifting phenomenon) and/or stripping (or a peeling phenomenon) of a layer at an interface between the pad PP and the pad insulation layer 116a.

One or more second pad insulation layers 150a and 163a may be disposed on the pad insulation layer 116a.

The one or more second pad insulation layers 150a and 163a may be disposed or formed on the first insulation layer 112 to surround each of the plurality of insulation patterns or the pad insulation layer 116a. The one or more second pad insulation layers 150a and 163a may be disposed or formed on the first insulation layer 112 to cover or surround each of the plurality of insulation patterns or the pad insulation layer 116a, between two pads PP adjacent to each other along a first direction X or a second direction Y. For example, the one or more second pad insulation layers 150a and 163a may cover the periphery portion of each of the plurality of pads PP and may contact or directly contact the first insulation layer 112 exposed between two pads PP adjacent to each other along the first direction X or the second direction Y. Thus, each of the plurality of insulation patterns or the pad insulation layer 116a may be surrounded or sealed by a second pad pattern PP2, a first insulation layer 112, and the one or more second pad insulation layers 150a and 163a.

According to an example embodiment of the present disclosure, the one or more second pad insulation layers 150a and 163a may include one or more of a lower insulation layer 150a and an upper insulation layer 163a. The lower insulation layer 150a and the upper insulation layer 163a may be as described above with reference to FIGS. 6 and 7. Thus, repetitive descriptions thereof are omitted.

In a pad area PA, at least one of the second pad insulation layers 150a and 163a and the pad insulation layer 116a may cover each of a plurality of link lines LL arranged between two adjacent pads PP along the first direction X.

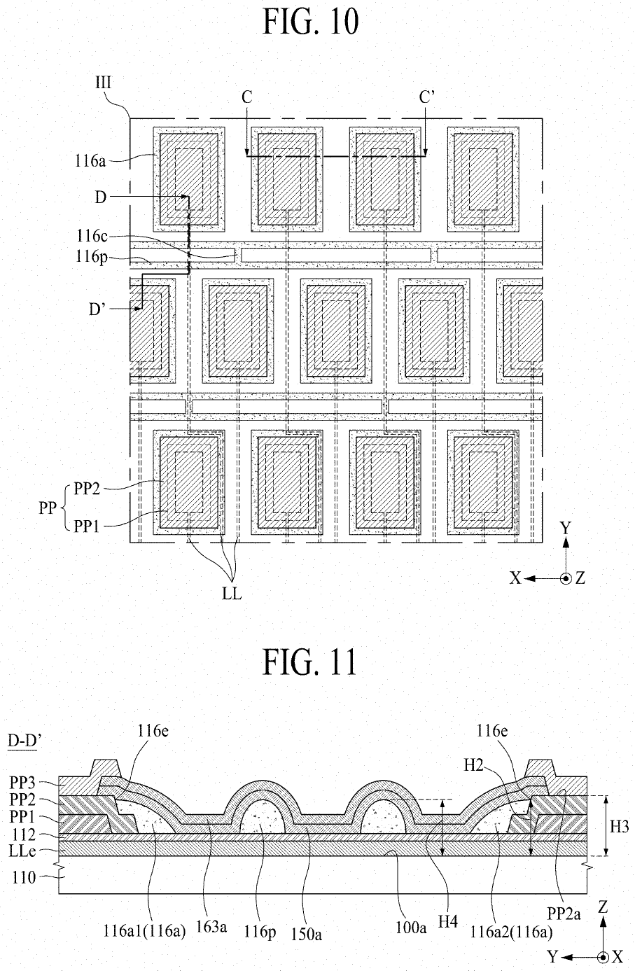

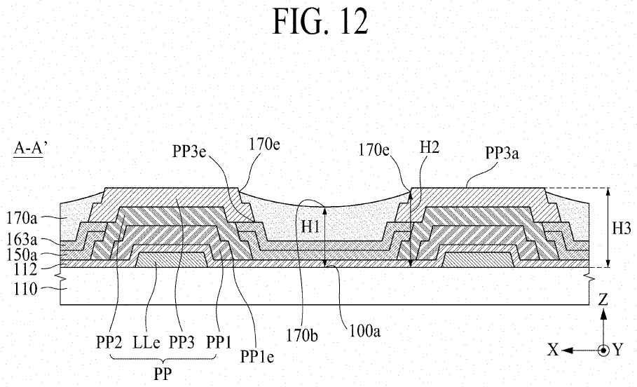

FIG. 10 is an example enlarged view of a region III of FIG. 1. FIG. 11 is an example cross-sectional view taken along line D-D′ of FIG. 10. FIGS. 10 and 11 illustrate an example embodiment where one or more dummy patterns are further provided in the pad area PA or the display apparatus described above with reference to FIGS. 8 and 9. Therefore, in the following description, descriptions of the elements other than one or more dummy patterns and elements relevant thereto may be omitted or briefly given. FIG. 9 is an example cross-sectional view taken along line C-C′ of FIG. 10 (and FIG. 8).

As illustrated in FIGS. 9 to 11, a pad insulation layer 116a of a display apparatus (or a pad area PA) according to another example embodiment of the present disclosure or the display apparatus (or the pad area PA) described above with reference to FIGS. 7 to 9 may further include one or more dummy patterns 116p. The pad insulation layer 116a may further include the one or more dummy patterns 116p between two insulation patterns 116a1 and 116a2 adjacent to each other along a second direction Y.

The one or more dummy patterns 116p may include a line shape configured in a region between two insulation patterns 116a1 and 116a2 adjacent to each other along the second direction Y. For example, the one or more dummy patterns 116p may include a line shape parallel to a first direction X.

The pad insulation layer 116a may further include a plurality of dummy patterns (or dummy insulation patterns) 116p between two insulation patterns 116a1 and 116a2 adjacent to each other along the second direction Y.

The plurality of dummy patterns 116p may be disposed between the two pads PP adjacent to each other along the second direction Y so as to be spaced apart from the insulation patterns 116a1 and 116a2. The plurality of dummy patterns 116p may have a line shape where dummy patterns 116p are parallel to and spaced apart from one another in a region between two insulation patterns 116a1 and 116a2 adjacent to each other along the second direction Y. For example, the plurality of dummy patterns 116p may include a line shape parallel to the first direction X.

The pad insulation layer 116a may further include one or more connection patterns 116c disposed between the plurality of dummy patterns 116p. The one or more connection patterns 116c may be disposed between the plurality of dummy patterns 116p in parallel with the second direction Y and may be connected with each of two insulation patterns 116a1 and 116a2 adjacent to each other along the second direction Y. For example, the pad insulation layer 116a may further include a plurality of connection patterns 116c which are disposed or connected between the plurality of dummy patterns 116p to have a certain interval along the first direction X.

For example, a fourth distance H4 between the top of each of the plurality of dummy patterns 116p and the substrate 110 may be the same as the second distance H2. The fourth distance H4 may be smaller than the third distance H3.

The plurality of dummy patterns 116p may be disposed to overlap a region between a plurality of bumps 210 disposed on a rear surface of the driving circuit 220 illustrated in FIG. 5. The plurality of dummy patterns 116p may be disposed between a substrate 110 and the rear surface (or the lower surface) of the driving circuit 220 between the plurality of bumps 210. Thus, the plurality of dummy patterns 116p may fill a portion of a space between the substrate 110 and the rear surface of the driving circuit 220. For example, the plurality of dummy patterns 116p may be configured to support an adhesive member 200 or the rear surface (or the lower surface) of the driving circuit 220, in a region between the plurality of bumps 210. For example, the plurality of dummy patterns 116p may act as a supporter which supports the adhesive member 200 or the rear surface of the driving circuit 220, in the region between the plurality of bumps 210. For example, the plurality of dummy patterns 116p may support the adhesive member 200 between the plurality of bumps 210. Therefore, when heat and pressure are applied for attaching (or mounting) the driving circuit 220 on the circuit disposition region 180 of the display panel, the process stability of an attachment process of the driving circuit 220 may be enhanced by supporting the adhesive member 200 between the plurality of bumps 210, and the occurrence of a void (or an air gap) between the adhesive member 200 or the rear surface (or the lower surface) of the driving circuit 220 may be minimized or prevented. Accordingly, the adhesive member 200 may contact or directly contact the whole rear surface (or the lower surface) of the driving circuit 220 including the plurality of bumps 210, may contact or directly contact the plurality of pads PP, and may fill a region between the plurality of pads PP. Therefore, an adhesive force between the driving circuit 220, the adhesive member 200, and the circuit disposition region 180 may increase based on the plurality of dummy patterns 116p.

One or more second pad insulation layers 150a and 163a may be disposed on the pad insulation layer 116a.

The one or more second pad insulation layers 150a and 163a may be disposed on the first insulation layer 112 to surround each of the plurality of dummy patterns 116p and the plurality of insulation patterns or the pad insulation layer 116a. Except for the one or more second pad insulation layers 150a and 163a being configured to additionally cover the plurality of dummy patterns 116p between two insulation patterns 116a1 and 116a2 adjacent to each other along the second direction Y, the one or more second pad insulation layers 150a and 163a may be as described above with reference to FIGS. 8 and 9. Thus, repetitive descriptions thereof are omitted.

In a pad area PA, at least one of the second pad insulation layers 150a and 163a and the pad insulation layer 116a may cover each of a plurality of link lines LL arranged between two adjacent pads PP along the first direction X. Some of the plurality of link lines LL may overlap a corresponding connection pattern 116c of the plurality of connection patterns 116c.

FIG. 12 is an example cross-sectional view taken along line A-A′ of FIG. 3. FIG. 12 illustrates an example embodiment implemented by modifying the pad PP, the pad insulation layer, and the one or more second pad insulation layers illustrated in FIGS. 1 to 7. Therefore, in the following description, descriptions of the other elements except a pad, a pad insulation layer, one or more second pad insulation layers, and elements relevant thereto are omitted or will be briefly given.

As shown in FIGS. 3 and 12, a pad area PA according to another example embodiment of the present disclosure may include a plurality of pads PP, a plurality of link lines LL, and a pad insulation layer 170a.

Each of the plurality of pads PP may include at least one of a link line extension portion LLe, a first insulation layer 112, a first pad pattern PP1, a second pad pattern PP2, and a third pad pattern PP3, which are on the substrate 110. At least some of the elements included in a pad PP according to an example embodiment of the present disclosure may be omitted, or another element may be added.

Except for a shape of each of the third pad patterns PP3, each of the plurality of pads PP may be configured to be equal to the pad PP described above with reference to FIGS. 3 to 7. Thus, repetitive descriptions thereof are omitted.

In each of the plurality of pads PP, the third pad pattern PP3 may be disposed to cover the second pad pattern PP2. The third pad pattern PP3 may be disposed to cover at least a portion of a lateral surface and an uppermost surface (or an uppermost flat surface) of the second pad pattern PP2. The third pad pattern PP3 may be disposed on the second pad pattern PP2 so as to be electrically connected with or contact the second pad pattern PP2. For example, the third pad pattern PP3 may be connected with or contact at least a portion of the lateral surface and the uppermost surface (or the uppermost flat surface) of the second pad pattern PP2.

The pad insulation layer 170a may be disposed on a pad area PA of the substrate 110 corresponding to a region between the plurality of pads PP. The pad insulation layer 170a may be disposed on the first insulation layer 112 of a pad area corresponding to a region between the plurality of pads PP. The pad insulation layer 170a may include the same material as that of the third planarization layer 170 of the display area A/A. As another example embodiment of the present disclosure, the pad insulation layer 170a may be a touch protection layer, an uppermost protection layer, or an organic insulating layer, but embodiments of the present disclosure are not limited thereto.

The pad insulation layer 170a may be formed along with a third planarization layer 170 in a display area A/A to simplify a manufacturing process, but embodiments of the present disclosure are not limited thereto.

A periphery portion of the pad insulation layer 170a may cover a periphery portion or a lateral surface of the third pad pattern PP3. For example, the periphery portion of the pad insulation layer 170a may cover a lateral surface, and not an uppermost surface PP3a, of the third pad pattern PP3. The periphery portion of the pad insulation layer 170a may cover the periphery portion (or a lateral surface), and not the uppermost surface (or an upper flat surface) PP3a, of the third pad pattern PP3, or may contact or directly contact a periphery portion or a lateral surface of the second pad pattern PP2. For example, the uppermost surface (or an uppermost flat surface) PP3a of the third pad pattern PP3 may not overlap the pad insulation layer 170a or may not be covered by the pad insulation layer 170a. For example, both ends 170e of the pad insulation layer 170a disposed between two adjacent pads PP may not overlap a first pad pattern PP1 and may overlap the periphery portion of the second pad pattern PP2. For example, the both ends 170e of the pad insulation layer 170a disposed between two adjacent pads PP may be located or disposed along a first direction X between an end PPle of the first pad pattern PP1 and an end PP3e of the third pad pattern PP3. For example, an uppermost surface PP3a of the third pad pattern PP3 may be disposed or configured more upward than a periphery portion (or the both ends) 170e of the pad insulation layer 170a.

According to an example embodiment of the present disclosure, a first distance H1 between the substrate 110 and a center portion 170b of the pad insulation layer 170a may be smaller than a second distance H2 between the substrate 110 and the periphery portion (or the end) 170e of the pad insulation layer 170a. For example, the first distance (or a first shortest distance) H1 between a first surface (or an upper surface) 100a of the substrate 110 and the center portion 170b of the pad insulation layer 170a may be smaller than the second distance (or a second shortest distance) H2 between the both ends 170e of the pad insulation layer 170a and the first surface (or the upper surface) 100a of the substrate 110.

According to another example embodiment of the present disclosure, the first distance H1 may be less than or equal to a third distance H3 between the substrate 110 and an uppermost surface PP3a of the pad PP. For example, the first distance H1 may be less than or equal to the third distance H3 between the substrate 110 and the uppermost surface PP3a of the third pad pattern PP3. For example, the first distance H1 may be less than or equal to the third distance H3 between the uppermost surface PP3a of the third pad pattern PP3 and the first surface (or the upper surface) 100a of the substrate 110. For example, the second distance H2 may be less than or equal to the third distance H3. For example, the second distance H2 may be greater than or equal to the first distance H1 and may be less than or equal to the third distance H3.

According to another example embodiment of the present disclosure, a thickness of the pad insulation layer 170a may decrease progressively toward the center portion 170b from the both ends 170e thereof. Accordingly, an upper surface (or a top surface) of the pad insulation layer 170a may include a non-flat structure. For example, the upper surface (or the top surface) of the pad insulation layer 170a may be concave, or may include a concave curved structure. Therefore, as described above with reference to FIG. 5, stress applied to the pad insulation layer 170a by a volume variation of the adhesive member 200 may be minimized or reduced, thereby preventing or minimizing the partial detachment (or a layer-lifting phenomenon) and/or stripping (or a peeling phenomenon) of a layer at an interface between the pad PP and the pad insulation layer 170a.

The pad area PA according to an example embodiment of the present disclosure may further include one or more second pad insulation layers 150a and 163a.

The one or more second pad insulation layers 150a and 163a may be disposed or located between the pad insulation layer 170a and the substrate 110, in a region between the plurality of pads PP.

The one or more second pad insulation layers 150a and 163a may be disposed between the plurality of pads PP to cover at least a portion of the periphery portion or the lateral surface of the second pad pattern PP2. A periphery portion of each of the one or more second pad insulation layers 150a and 163a may be disposed or interposed between the second pad pattern PP2 and the third pad pattern PP3. For example, the periphery portion of each of the one or more second pad insulation layers 150a and 163a may be disposed or interposed between an inclined lateral surface of the second pad pattern PP2 and a rear (or lower) periphery portion of the third pad pattern PP3. Accordingly, the rear (or lower) periphery portion of the third pad pattern PP3 may cover or contact a portion of the inclined lateral surface of the second pad pattern PP2 and the periphery portion of the one or more second pad insulation layers 150a and 163a.

The periphery portion of the one or more second pad insulation layers 150a and 163a may cover an interface between the rear (or lower) periphery portion of the third pad pattern PP3 and the second pad pattern PP2 and may be coupled to the rear (or lower) periphery portion of the third pad pattern PP3, thereby minimizing or preventing the stripping (or a peeling phenomenon) of the third pad pattern PP3 caused by stress which is accumulated in the pad insulation layer 170a due to a volume variation (or contraction) of the adhesive member 200.

The one or more second pad insulation layers 150a and 163a may include one or more of a lower insulation layer 150a and an upper insulation layer 163a. The lower insulation layer 150a and the upper insulation layer 163a may be as described above with reference to FIGS. 6 and 7. Thus, repetitive descriptions thereof are omitted.

The pad insulation layer 170a may cover the one or more second pad insulation layers 150a and 163a disposed between the plurality of pads PP and may cover a periphery portion (or a lateral surface) of each of the plurality of pads PP. For example, the pad insulation layer 170a may cover the one or more second pad insulation layers 150a and 163a disposed between the plurality of pads PP and may cover the periphery portion (or the lateral surface) of the third pad pattern PP3.

The display apparatus according to an example embodiment of the present disclosure may be applied to mobile apparatuses, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theater apparatuses, theater display apparatuses, TVs, wall paper display apparatuses, signage apparatuses, game machines, notebook computers, monitors, cameras, camcorders, and home appliances, or the like. In addition, the display apparatus according to some example embodiments of the present disclosure may be applied to organic light-emitting lighting apparatuses or inorganic light-emitting lighting apparatuses.

A display apparatus according to an embodiment of the present disclosure will be described below.

A display apparatus according to an embodiment of the present disclosure may comprise a substrate including a display portion and a non-display portion at a periphery of the display portion and including a pad area, a plurality of signal lines at the display portion and the non-display portion, a plurality of pads respectively connected with the plurality of signal lines at the pad area, and an insulation layer on the substrate between the plurality of pads, wherein a first distance between the substrate and a center portion of the insulation layer may be smaller than a second distance between the substrate and a periphery portion of the insulation layer.

According to some embodiments of the present disclosure, each of the plurality of pads may comprise a first pad pattern connected with a corresponding signal line among the plurality of signal lines, and a second pad pattern covering the first pad pattern, and the periphery portion of the insulation layer covers a periphery portion of the second pad pattern.

According to some embodiments of the present disclosure, an uppermost surface of the second pad pattern may be more upward than the periphery portion of the insulation layer.

According to some embodiments of the present disclosure, the first distance between the substrate and the center portion of the insulation layer may be less than or equal to a third distance between the substrate and the uppermost surface of the second pad pattern.

According to some embodiments of the present disclosure, the display apparatus may further comprise one or more second insulation layers covering the periphery portion of the second pad pattern and the insulation layer.

According to some embodiments of the present disclosure, each of the plurality of pads may further comprise a third pad pattern connected with the second pad pattern and covering a periphery portion of each of the one or more second insulation layers.

According to some embodiments of the present disclosure, the periphery portion of each of the one or more second insulation layers may be between the periphery portion of the second pad pattern and a periphery portion of the third pad pattern.

According to some embodiments of the present disclosure, the plurality of pads may be disposed at a certain interval along each of a first direction and a second direction intersecting with the first direction, and the insulation layer may comprise a plurality of insulation patterns respectively surrounding the plurality of pads.

According to some embodiments of the present disclosure, the plurality of insulation patterns may be spaced apart from one another between two pads adjacent to each other along the second direction.

According to some embodiments of the present disclosure, the display apparatus may further comprise one or more second insulation layers covering the periphery portion of the second pad pattern and each of the plurality of insulation patterns.

According to some embodiments of the present disclosure, the insulation layer may further comprise one or more dummy patterns between two of the plurality of insulation patterns adjacent to each other in the second direction.

According to some embodiments of the present disclosure, the display apparatus may further comprise one or more second insulation layers covering each of the periphery portion of the second pad pattern, the plurality of insulation patterns, and the one or more dummy patterns.

According to some embodiments of the present disclosure, the display portion may comprise a plurality of pixels each including a thin film transistor connected with a corresponding one of the plurality of signal lines, an overcoat layer covering the thin film transistor, a first electrode disposed on the overcoat layer and connected with the thin film transistor, a bank layer covering a periphery portion of the first electrode, a light emitting layer on the first electrode, and a second electrode on the light emitting layer and the bank layer. The insulation layer may comprise a same material as a material of the bank layer or the overcoat layer.

According to some embodiments of the present disclosure, the display portion may comprise a plurality of pixels each including a thin film transistor connected with a corresponding one of the plurality of signal lines, an overcoat layer covering the thin film transistor, a first electrode disposed on the overcoat layer and connected with the thin film transistor, a bank layer covering a periphery portion of the first electrode, a light emitting layer on the first electrode, a second electrode on the light emitting layer and the bank layer, an encapsulation portion on the second electrode, a touch insulation layer on the encapsulation portion, and a touch sensing portion on the touch insulation layer. The insulation layer may comprise a same material as a material of the bank layer or the overcoat layer, and the one or more second insulation layers may comprise a same material as a material of the touch insulation layer.

According to some embodiments of the present disclosure, the touch sensing portion may comprise a first touch electrode layer on the touch insulation layer, an interlayer insulation layer covering the first touch electrode layer, and a second touch electrode layer on the interlayer insulation layer. The one or more second insulation layer may comprise a lower insulation layer including the same material as the material of the touch insulation layer, and an upper insulation layer on the lower insulation layer and including a same material as a material of the interlayer insulation layer.

According to some embodiments of the present disclosure, each of the plurality of pads may comprise a first pad pattern connected with a corresponding signal line among the plurality of signal lines, a second pad pattern covering the first pad pattern, and a third pad pattern covering the second pad pattern, and the periphery portion of the insulation layer may cover a periphery portion of the third pad pattern.

According to some embodiments of the present disclosure, an uppermost surface of the third pad pattern may be on the periphery portion of the insulation layer.

According to some embodiments of the present disclosure, the first distance between the substrate and the center portion of the insulation layer may be less than or equal to a third distance between the substrate and an uppermost surface of the second pad pattern.

According to some embodiments of the present disclosure, the display portion may comprise an encapsulation portion on a plurality of pixels, a touch insulation layer on the encapsulation portion, a touch sensing portion on the touch insulation layer, and a touch protection layer on the touch sensing portion, and the insulation layer may comprise a same material as a material of the touch protection layer.

According to some embodiments of the present disclosure, the display apparatus may further comprise one or more second insulation layers between the substrate and the insulation layer.

According to some embodiments of the present disclosure, a periphery portion of each of the one or more second insulation layers may be between a periphery portion of the second pad pattern and a periphery portion of the third pad pattern.

According to some embodiments of the present disclosure, the display portion may comprise an encapsulation portion on a plurality of pixels, a touch insulation layer on the encapsulation portion, a first touch electrode layer on the touch insulation layer, an interlayer insulation layer covering the first touch electrode layer, a second touch electrode layer on the interlayer insulation layer, and a touch protection layer on the second touch electrode layer, the insulation layer may comprises a same material as a material of the touch protection layer. The one or more second insulation layer may comprise a lower insulation layer including a same material as a material of the touch insulation layer, and an upper insulation layer on the lower insulation layer and including a same material as a material of the interlayer insulation layer.

According to some embodiments of the present disclosure, the display apparatus may further comprise a driving circuit connected with the plurality of pads.

According to some embodiments of the present disclosure, the driving circuit may comprise a plurality of terminals electrically connected with the plurality of pads through a plurality of conductive particles, respectively.

A display apparatus according an example embodiment of the present disclosure may comprise a substrate including a display region and a non-display region surrounding the display region, a plurality of pads disposed in the non-display region and respectively connected with a plurality of signal lines for supplying signals to a plurality of pixels disposed in the display region, and an insulation layer disposed on the substrate and contacting with at least a portion of a side surface of each of the plurality of pads, wherein a thickness of the insulation layer may decrease progressively toward a center portion of the insulation layer from an end of the insulation layer.

According to some embodiments of the present disclosure, the insulation layer may not contact with an uppermost surface of any of the plurality of pads.

It will be apparent to those skilled in the art that various modifications and variations can be made in the present disclosure without departing from the spirit or scope of the disclosures. Thus, it is intended that the present disclosure cover such modifications and variations of this disclosure.

What is claimed is:

1. A display apparatus, comprising:
a substrate including:
a display portion; and
a non-display portion at a periphery of the display portion and including a pad area;
a plurality of signal lines at the display portion and the non-display portion;
a plurality of pads respectively connected with the plurality of signal lines in the pad area; and
an insulation layer on the substrate between the plurality of pads,
wherein a first distance between the substrate and a center portion of the insulation layer is smaller than a second distance between the substrate and a periphery portion of the insulation layer.

2. The display apparatus of claim 1, wherein each of the plurality of pads comprises:
a first pad pattern connected with a corresponding signal line among the plurality of signal lines; and
a second pad pattern covering the first pad pattern, and
wherein the periphery portion of the insulation layer covers a periphery portion of the second pad pattern.

3. The display apparatus of claim 2, wherein an uppermost surface of the second pad pattern is more upward than the periphery portion of the insulation layer.

4. The display apparatus of claim 3, wherein the first distance between the substrate and the center portion of the insulation layer is less than or equal to a third distance between the substrate and the uppermost surface of the second pad pattern.

5. The display apparatus of claim 2, further comprising one or more second insulation layers covering the periphery portion of the second pad pattern and the insulation layer.

6. The display apparatus of claim 5, wherein each of the plurality of pads further comprises a third pad pattern connected with the second pad pattern and covering a periphery portion of each of the one or more second insulation layers.

7. The display apparatus of claim 6, wherein the periphery portion of each of the one or more second insulation layers is between the periphery portion of the second pad pattern and a periphery portion of the third pad pattern.

8. The display apparatus of claim 2, wherein the plurality of pads are disposed at a certain interval along each of a first direction and a second direction intersecting with the first direction, and
wherein the insulation layer comprises a plurality of insulation patterns respectively surrounding the plurality of pads.

9. The display apparatus of claim 8, wherein the plurality of insulation patterns are spaced apart from one another between two pads adjacent to each other along the second direction.

10. The display apparatus of claim 9, further comprising one or more second insulation layers covering the periphery portion of the second pad pattern and each of the plurality of insulation patterns.

11. The display apparatus of claim 9, wherein the insulation layer further comprises one or more dummy patterns between two of the plurality of insulation patterns adjacent to each other in the second direction.

12. The display apparatus of claim 11, further comprising one or more second insulation layers covering each of the periphery portion of the second pad pattern, the plurality of insulation patterns, and the one or more dummy patterns.

13. The display apparatus of claim 1, wherein the display portion comprises:
a plurality of pixels each including a thin film transistor connected with a corresponding one of the plurality of signal lines;
an overcoat layer covering the thin film transistor;
a first electrode disposed on the overcoat layer and connected with the thin film transistor;
a bank layer covering a periphery portion of the first electrode;
a light emitting layer on the first electrode; and
a second electrode on the light emitting layer and the bank layer, and
wherein the insulation layer comprises a same material as a material of the bank layer or the overcoat layer.

14. The display apparatus of claim 5, wherein the display portion comprises:
a plurality of pixels each including a thin film transistor connected with a corresponding one of the plurality of signal lines;
an overcoat layer covering the thin film transistor;
a first electrode disposed on the overcoat layer and connected with the thin film transistor;
a bank layer covering a periphery portion of the first electrode;
a light emitting layer on the first electrode;
a second electrode on the light emitting layer and the bank layer;
an encapsulation portion on the second electrode;
a touch insulation layer on the encapsulation portion; and
a touch sensing portion on the touch insulation layer,
wherein the insulation layer comprises a same material as a material of the bank layer or the overcoat layer, and
wherein the one or more second insulation layers comprise a same material as a material of the touch insulation layer.

15. The display apparatus of claim 14, wherein the touch sensing portion comprises:
a first touch electrode layer on the touch insulation layer;
an interlayer insulation layer covering the first touch electrode layer; and
a second touch electrode layer on the interlayer insulation layer, and
wherein the one or more second insulation layer comprises:
a lower insulation layer including the same material as the material of the touch insulation layer; and
an upper insulation layer on the lower insulation layer and including a same material as a material of the interlayer insulation layer.

16. The display apparatus of claim 1, wherein each of the plurality of pads comprises:
a first pad pattern connected with a corresponding signal line among the plurality of signal lines;
a second pad pattern covering the first pad pattern; and
a third pad pattern covering the second pad pattern, and
wherein the periphery portion of the insulation layer covers a periphery portion of the third pad pattern.

17. The display apparatus of claim 16, wherein an uppermost surface of the third pad pattern is on the periphery portion of the insulation layer.

18. The display apparatus of claim 17, wherein the first distance between the substrate and the center portion of the insulation layer is less than or equal to a third distance between the substrate and an uppermost surface of the second pad pattern.

19. The display apparatus of claim 16, wherein the display portion comprises:
an encapsulation portion on a plurality of pixels;
a touch insulation layer on the encapsulation portion;
a touch sensing portion on the touch insulation layer; and
a touch protection layer on the touch sensing portion, and
wherein the insulation layer comprises a same material as a material of the touch protection layer.

20. The display apparatus of claim 16, further comprising one or more second insulation layers between the substrate and the insulation layer.

21. The display apparatus of claim 20, wherein a periphery portion of each of the one or more second insulation layers is between a periphery portion of the second pad pattern and a periphery portion of the third pad pattern.

22. The display apparatus of claim 21, wherein the display portion comprises:
an encapsulation portion on a plurality of pixels;
a touch insulation layer on the encapsulation portion;
a first touch electrode layer on the touch insulation layer;
an interlayer insulation layer covering the first touch electrode layer;
a second touch electrode layer on the interlayer insulation layer; and
a touch protection layer on the second touch electrode layer,
wherein the insulation layer comprises a same material as a material of the touch protection layer, and
wherein the one or more second insulation layer comprises:
a lower insulation layer including a same material as a material of the touch insulation layer; and
an upper insulation layer on the lower insulation layer and including a same material as a material of the interlayer insulation layer.

23. The display apparatus of claim 1, further comprising a driving circuit connected with the plurality of pads.

24. The display apparatus of claim 23, wherein the driving circuit comprises a plurality of terminals electrically connected with the plurality of pads through a plurality of conductive particles, respectively.

25. A display apparatus, comprising:
a substrate including a display region and a non-display region surrounding the display region;
a plurality of pads disposed in the non-display region and respectively connected with a plurality of signal lines for supplying signals to a plurality of pixels disposed in the display region; and
an insulation layer disposed on the substrate and contacting with at least a portion of a side surface of each of the plurality of pads,
wherein a thickness of the insulation layer decreases progressively toward a center portion of the insulation layer from an end of the insulation layer.

26. The display apparatus of claim 25, wherein the insulation layer does not contact with an uppermost surface of any of the plurality of pads.
